(19) United States
(12) Patent Application Publication
(10) Pub. No.: US 2021/0307165 A1
(43) Pub. Date: Sep. 30, 2021

(54) Elastic Connecting Component and Method for Manufacturing the Same, and Elastic Electronic Device and Method for Manufacturing the Same

(71) Applicant: Shenzhen Royole Technologies Co., Ltd., Shenzhen (CN)

(72) Inventor: Jiahao Kang, Shenzhen (CN)

(21) Appl. No.: 17/213,903

(22) Filed: Mar. 26, 2021

(30) Foreign Application Priority Data
Mar. 26, 2020 (CN) 202010224185.X

(51) Int. Cl. H05K 1/03; H05K 1/11; H05K 3/40

(52) U.S. Cl. CPC H05K 1/0393; H05K 1/118; H05K 2201/0133; H05K 1/115; H05K 3/4038

(57) ABSTRACT

Disclosed is an elastic connecting component, including an elastomer, and an elastic conductor in the elastomer, wherein the elastic conductor includes a first conductor, a second conductor, and a third conductor electrically connected between the first conductor and the second conductor; a plane where the second conductor and the third conductor are positioned has a preset angle in relation to the first conductor, and the preset angle is between 0° and 180°. Further disclosed is a method for manufacturing the elastic connecting component, an elastic electronic device and a method for manufacturing the same. A three-dimensional configuration of the elastic conductor in the elastic connecting component enables the elastic conductor to have a better tensile elongation performance.

### CROSS-REFERENCE TO RELATED APPLICATIONS

This application is based upon and claims priority to Chinese Patent Application No. 202010224185.X, filed with the Chinese Patent Office on Mar. 26, 2020, titled “ELASTIC CONNECTING COMPONENT AND METHOD FOR MANUFACTURING THE SAME, AND ELASTIC ELECTRONIC DEVICE AND METHOD FOR MANUFACTURING THE SAME”, the entire contents of which are incorporated herein by reference.

### TECHNICAL FIELD

This application relates to the field of electronics, and more particularly, to an elastic connecting component and a method for manufacturing the same, and an elastic electronic device and a method for manufacturing the same.

### BACKGROUND

With the rapid development of information technology, terminals such as smartphones and tablet computers have become indispensable to people's daily life. In the technical field of flexible display, a flexible terminal includes many important components, and a connecting component is one of them. A connecting component in a flexible terminal electrically connects a display, a circuit board, and a power source as well as other electronic elements in the flexible terminal.

### SUMMARY

In a first aspect of this application, an elastic connecting component is provided, including an elastomer and an elastic conductor in the elastomer, wherein the elastic conductor includes a first conductor, a second conductor, and a third conductor electrically connected between the first conductor and the second conductor, a plane where the second conductor and the third conductor are positioned has a preset angle in relation to the first conductor, and the preset angle is between 0° and 180°.

In a second aspect of this application, an elastic electronic device is provided, including the elastic connecting component as described above.

In a third aspect of this application, a method for manufacturing the elastic connecting component is provided, including:

providing a first base;

forming a first conductor on a side of the first base;

forming an intermediate layer on one side of the first base facing the first conductor, wherein the intermediate layer covers the first conductor;

forming a through hole in the intermediate layer to expose the first conductor partially, and forming a third conductor electrically connected with the first conductor in the through hole;

forming a second conductor on a surface of the intermediate layer opposite the first base, wherein the second conductor is connected with the third conductor, a plane where the second conductor and the third conductor are positioned has a preset angle in relation to the first conductor, and the preset angle is between 0° and 180°; and

forming a sub-elastomer on a surface of the second conductor opposite the first base, wherein the sub-elastomer covers the second conductor.

In a fourth aspect of this application, a method for manufacturing the elastic electronic device is provided, including:

providing a second base;

forming a first conductor and a connecting terminal on a side of the second base;

forming an intermediate layer on a side of the second base facing the first conductor, wherein the intermediate layer covers the first conductor;

forming a through hole in the intermediate layer to expose the first conductor partially, and forming a third conductor electrically connected with the first conductor in the through hole;

forming a second conductor on a surface of the intermediate layer opposite the second base, wherein the second conductor is connected with the third conductor, a plane where the second conductor and the third conductor are positioned has a preset angle in relation to the first conductor, the preset angle is between 0° and 180°, and the first conductor, the second conductor, and the third conductor form the elastic conductor;

removing the intermediate layer, and providing an electronic element on a side of the second base, wherein the electronic element is electrically connected with the elastic conductor through the connecting terminal; and

forming a sixth sub-elastomer on a side of the second base facing the electronic element, wherein the sixth sub-elastomer covers the electronic element and the elastic conductor.

### BRIEF DESCRIPTION OF THE DRAWINGS

To explain the technical solution in the embodiments of this application more clearly, a brief description of the drawings as necessary for the embodiments will be provided. Apparently, the drawings in the following description are only some but not all of the embodiments of this application. Those of ordinary skill in the art can obtain other drawings based on these drawings without inventive efforts.

FIG. 1 is a structural schematic view of an elastic connecting component according to an embodiment of this application.

FIG. 2 is a structural schematic view of an elastic connecting component according to an embodiment of this application is pulled in tension.

FIG. 3 is a structural schematic view of an elastic conductor in the elastic connecting component according to an embodiment of this application.

FIG. 4 is a structural schematic view of a two-dimensional connecting component.

FIG. 5 are structural schematic views of an elastic conductor in an elastic connecting component according to an embodiment of this application being gradually pulled in tension, the uppermost view showing a state when the elastic conductor is not pulled in tension, and the three views below showing the states when the elastic conductor is gradually pulled in tension.

FIG. 6 is a structural schematic view of an elastic electronic device according to an embodiment of this application.

FIG. 7 is a structural schematic view of an elastic electronic device according to another embodiment of this application.

FIG. 8 is a flow chart illustrating a method for manufacturing an elastic connecting component according to an embodiment of this application.

FIG. 9 is a structural schematic view for each step in the method for manufacturing an elastic connecting component according to an embodiment of this application.

FIG. 10 is a flow chart illustrating a method for manufacturing an elastic connecting component according to another embodiment of this application.

FIG. 11 is a flow chart illustrating a method for manufacturing an elastic connecting component according to another embodiment of this application.

FIG. 12 is a structural schematic view for each step in the method for manufacturing an elastic connecting component of FIG. 11.

FIG. 13 is a flow chart illustrating a method for manufacturing an elastic electronic device according to an embodiment of this application.

### DETAILED DESCRIPTION

Preferred embodiments of this application are described below, and it is to be understood that numerous modifications and adaptations may be devised by those skilled in the art without departing from the spirit and scope of this application and shall fall within the scope of this application.

The terms like “first” and “second” in the description, the claims, and the drawings of this application are used for distinguishing between different objects and not for defining a particular order. Furthermore, the terms “include” and “have”, as well as any variations thereof, are intended to be a non-exclusive inclusion. For example, a process, method, system, product, or device that includes a list of steps or elements is not limited to the shown steps or elements, but optionally further includes steps or elements not shown, or optionally further includes other steps or elements inherent to such process, method, product, or device.

Reference herein to “an embodiment” means that a particular feature, structure, or characteristic described in connection with the embodiment may be included in at least one embodiment of the application. “Embodiments” in various places in the description do not necessarily all refer to the same one, nor independent or alternative ones exclusive to other embodiments. Those skilled in the art will appreciate explicitly and implicitly that the embodiments described herein may be combined with other embodiments.

In the prior art, it is contemplated in most cases to design the display or circuit board as elastically stretchable ones, however, most of the connecting components is made of flexible metal wires or organic wires, the flexibility and tensile elongation performance need to be further improved.

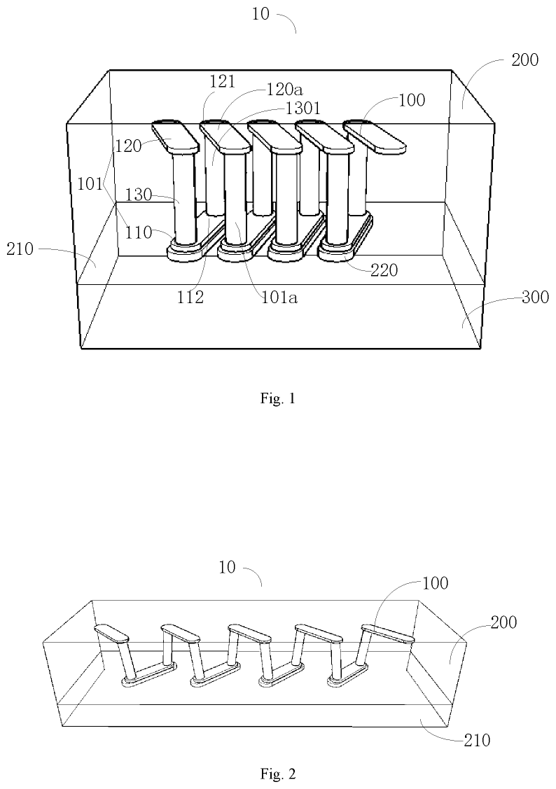

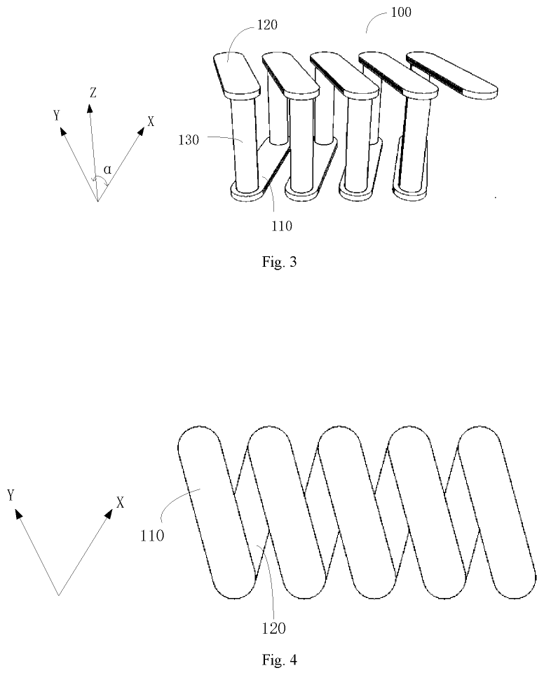

Referring to FIGS. 1 to 3, an embodiment of this application provides an elastic connecting component 10, including an elastomer 200 and an elastic conductor 100 in the elastomer 200. Herein, the elastomer 200 has elastic extensibility, so that the elastic connecting component 10 can be deformed and elongated. The elastic conductor 100 includes a first conductor 110, a second conductor 120, and a third conductor 130 electrically connected between the first conductor 110 and the second conductor 120, a plane where the second conductor 120 and the third conductor 130 are positioned has a preset angle α in relation to the first conductor 110, the preset angle α is between 0° and 180° (as shown in FIG. 3), i.e., the preset angle α is not equal to 0° or 180°. That is, the elastic conductor 100 is a three-dimensional structure rather than a two-dimensional planar structure. Herein, the elastic conductor 100 can be deformed and elongated when pulled in tension. In this application, the three-dimensional elastic conductor 100 has a better deformation and elongation capability than that of a two-dimensional structure, which will be exemplified below.

Referring to FIG. 4, a two-dimensional connecting component is shown and is formed by sequentially connecting first conductors 110 and second conductors 120, with an extension length defined only by lengths of the first conductors 110 and the second conductors 120. When pulled in tension, such a connecting component has a maximum length equaling the sum of the lengths of the first conductors 110 and the second conductors 120.

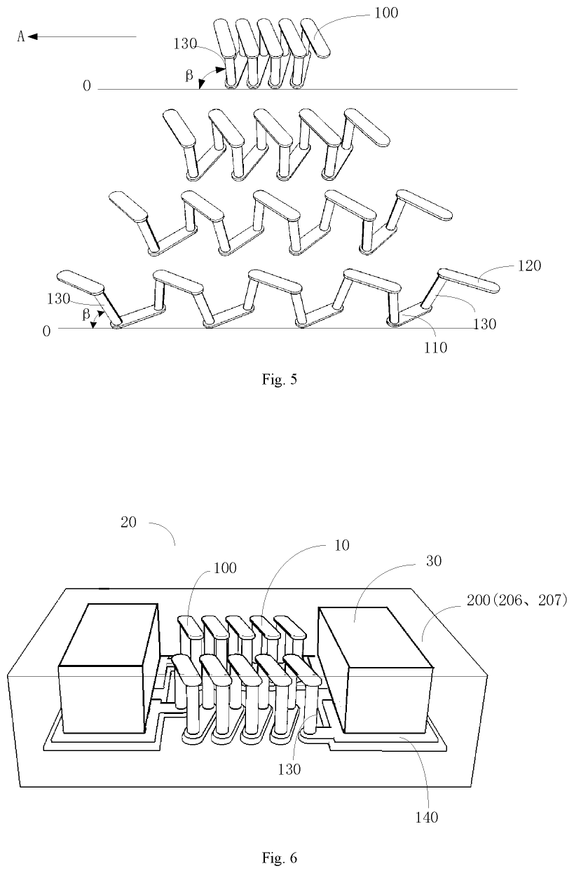

Referring again to FIG. 3, the elastic conductor 100 in FIG. 3 includes a plurality of first conductors 110, a plurality of second conductors 120, and a plurality of third conductors 130 connecting the first conductors 110 and the second conductors 120; for comparison, the pane where the third conductor 130 and the second conductor 120 are positioned is referred to as a plane formed by a third direction Z and a second direction Y, and the first conductor 110 is configured along a first direction X. In this embodiment, the third conductor 130 is perpendicular to the first conductor 110 and the second conductor 120, respectively, and the extension length of the elastic conductor 100 is increased because of the third conductor 130 configured in the third direction Z. Referring to FIG. 5, which shows schematic views of the elastic conductor 100 being gradually pulled in tension, the uppermost view in FIG. 5 shows the original state, and the lowermost view shows one of the states when the elastic conductor 100 is pulled in tension. The elastic conductor 100 has a maximum length when pulled to the greatest extent, which equals the sum of the lengths of the first conductors 110, the second conductors 120, and the third conductors 130 and is longer than that in the case of the two-dimensional structure.

It should be noted that FIG. 3 described above is only one embodiment of this application to illustrate the advantages of this application. In this application, the tensile elongation performance of the elastic conductor 100 will be increased as long as the plane where the second conductor 120 and the third conductor 130 are positioned has the preset angle α (between 0° and 180°) in relation to the first conductor 110 so that the elastic conductor 100 has a three-dimensional structure.

Referring again to FIG. 5, in a further embodiment, when an extension direction A of the elastic connecting component 10 is parallel to a horizontal plane O, an included angle β between the third conductor 130 and the horizontal plane O decreases when the elastic connecting component 10 is pulled in tension. The included angle β in the uppermost view in FIG. 5 is larger than the included angle β in the lowermost view in FIG. 5. That is, when the elastic connecting component 10 is placed on the horizontal plane O, the third conductor 130 gets closer to the horizontal plane when the elastic connecting component 10 is pulled to a greater extent. In the case that the elastic connecting component 10 is such pulled in tension that the third conductor 130 is parallel to the horizontal plane O, the extension length of the elastic connecting component 10 increases at least by the sum of the lengths of the third conductors 130; such an increase is not available without the configuration of the third conductors 130, which proves that the configuration of this application renders better tensile elongation performance than a two-dimensional elastomer.

It should be noted that the extension direction of the elastic connecting component 10 may have an angle in relation to the horizontal plane in an actual application of the elastic connecting component 10, for example, when the extension direction A of the elastic connecting component 10 is perpendicular to the horizontal plane O, the included angle β between the third conductor 130 and a vertical plane decreases when the elastic connecting component 10 is pulled in tension.

Referring again to FIG. 1, in a further embodiment, the elastomer 200 encases the elastic conductor 100 to protect the elastic conductor 100. The elastomer 200 protects the elastic conductor 100 from being damaged due to compression when the elastic connecting component 10 is in contact with other devices.

In a further embodiment, adjacent ones of the first conductors 110, the second conductors 120 and the third conductors 130 form a conductive unit 101, and the elastic conductor 100 includes at least one conductive unit 101. In this embodiment, the elastic conductor 100 includes a plurality of conductive units 101.

In a further embodiment, the first conductor 110 is parallel to the second conductor 120. In other embodiments, the first conductor 110 has an angle in relation to the second conductor 120. to facilitate manufacturing, in this embodiment, the first conductor 110 and the second conductor 120 are preferably configured parallel to each other.

In a further embodiment, the third conductor 130 is connected at adjacent ends of the first conductor 110 and the second conductor 120. In this embodiment, the first conductor 110 and the second conductor 120 are sequentially staggered, and the third conductor 130 connects adjacent ends of the first conductor 110 and the second conductor 120. In the case of a plurality of conductive units 101, two adjacent conductive units 101 are connected by the third conductor 130, as shown in FIG. 1, the third conductor 130 connects a second end 112 of the first conductor 110 in the conductive unit 101 and a first end 121 of the second conductor 120a in the conductive unit 101a13, wherein the first end 121 of the second conductor 120a faces an end of the elastic conductor 100, and the second end 112 of the first conductor 110 faces the other end of the elastic conductor 100 in relation to the first end 121 of the second conductor 120a.

In a further embodiment, the third conductor 130 is perpendicularly connected with the first conductor 110 and the second conductor 120, respectively, when the elastic connecting component 10 is not pulled in tension. In other embodiments, the third conductor 130 may have an acute angle or an obtuse angle in relation to the first conductor 110 and the second conductor 120, respectively.

In a further embodiment, the first conductor 110 and the second conductor 120 are sheet-like, and the third conductor 130 is cylindrical. In other embodiments, the first conductor 110, the second conductor 120, and the third conductor 130 may also be of other shapes, including, but not limited to, a cuboid, a triangular pyramid, an elliptical cylinder, or a shape combining various patterns.

In a further embodiment, the elastomer 200 includes a first surface 210, and the first conductor 110 is arranged closer to the first surface 210 of the elastomer 200 than the second conductor 120; the elastic connecting component 10 further includes an elastic base 300 attached to the first surface 210 of the elastomer 200. The elastic base 300 may be integrally formed with the elastomer 200 or they may be separately formed.

In a further embodiment, the elastomer 200 includes the first surface 210, and the first conductor 110 is arranged closer to the first surface 210 of the elastomer 200 than the second conductor 120; the elastomer 200 also includes a flexible layer 220 disposed on a surface of the first conductors 110 close to the first surface 210. The flexible layer 220 supports and protects the first conductors 110. In other embodiments, the flexible layer 220 may not be provided.

Referring to FIG. 6, an embodiment of this application also provides an elastic electronic device 20, including an elastic connecting component 10 according to any of the above embodiments.

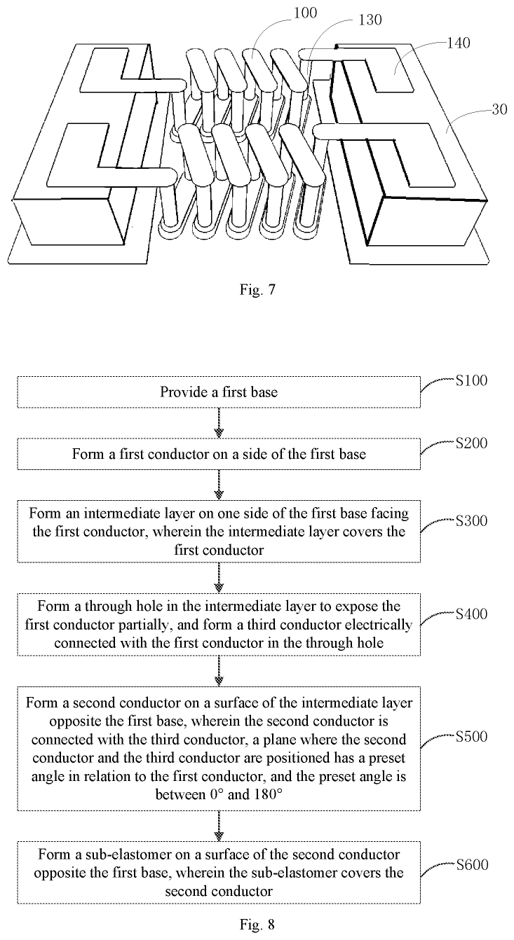

In a further embodiment, the elastic electronic device 20 further includes an electronic element 30 arranged in the elastomer 200 and electrically connected with the elastic conductor 100. In this embodiment, the elastic conductor 100 further includes a connecting terminal 140 that connects the elastic conductor 100 and the electronic element 30, and the connecting terminal 140 may be positioned below the electronic element 30, specifically, the connecting terminal 140 is connected with the third conductor 130 at an end portion of the elastic conductor 100. In other embodiments, as shown in FIG. 7, the connecting terminal 140 may also be connected with the elastic conductor 100 above the electronic element 30, specifically, the connecting terminal 140 is connected with the third conductor 130 at the end portion of the elastic conductor 100. In other embodiments, the connecting terminal 140 is connected with the first conductor 110 or the second conductor 120 at the end portion of the elastic conductor 100. Herein, the electronic element 30 may be determined in an actual application, including but not limited to LEDs, OLEDs, sensors, etc.

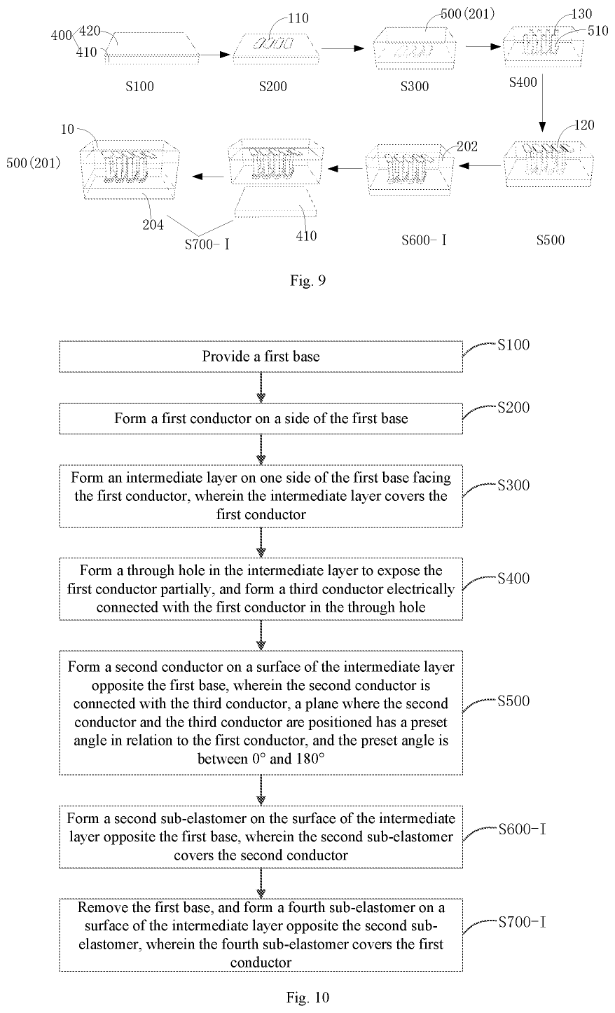

Referring to FIGS. 8 and 9, one of the methods for manufacturing the elastic connecting component 10 according to an embodiment of this application includes step S100, step S200, step S300, step S400, step S500, and step S600. The details are as follows.

Step S100, a first base 400 is provided. The first base 400 includes a first sub-base 410 and a flexible base 420 which are stacked, wherein the first sub-base 410 is a rigid base, including glass, a silicon wafer, etc.

Step S200, a first conductor 110 is formed on a side of the first base 400. Specifically, the first conductor 110 is formed on a surface of the flexible base 420 opposite the first sub-base 410.

The first conductor 110 may be made of conductive materials such as metal, organic polymer, and conductive ink. Herein, when a plurality of first conductors 110 are formed, the plurality of first conductors 110 are formed at intervals on a side of the first base 400. The plurality of first conductors 110 may be formed through deposition/plating, photolithographic etching, screen printing, inkjet printing, self-assembly, etc.

In this embodiment, after step S200, the method further includes reducing the flexible base 420 to the flexible layer 220, the flexible layer 220 at least coinciding with the first conductor 110. The flexible layer 220 supports and protects the first conductor 110. In other embodiments, the flexible layer 220 may not be formed.

Step S300, an intermediate layer 500 is formed on a side of the first base 400 facing the first conductor 110 and covers the first conductor 110. Specifically, an intermediate layer 500 is formed on a side of the first sub-base 410 facing the first conductor 110 and covers the first conductor 110 and the flexible layer 220.

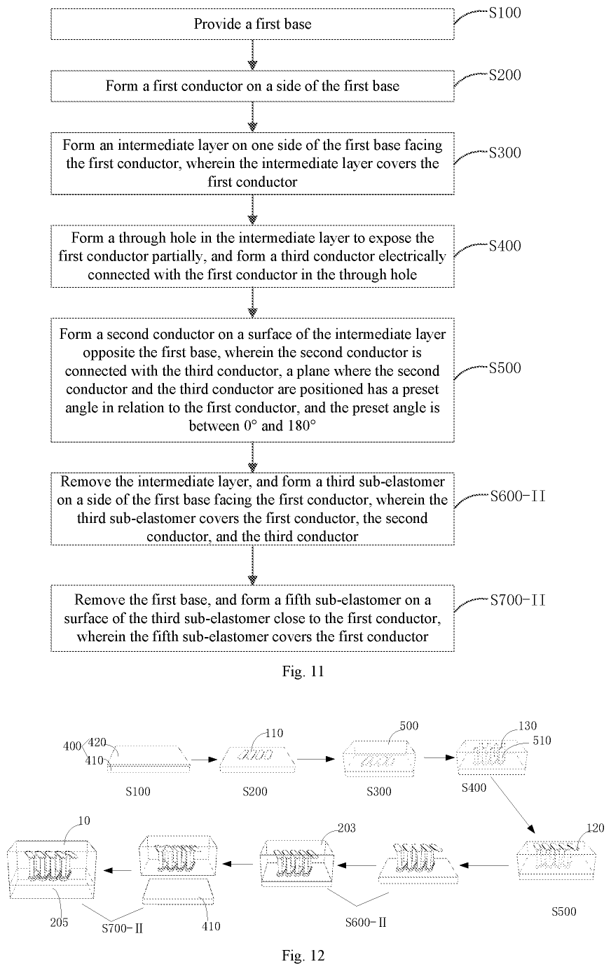

Herein, the intermediate layer 500 may be an elastomer or not an elastomer, the intermediate layer 500 can be removed in a subsequent step as appropriate if it is not an elastomer (see FIGS. 11 and 12), and then an elastomer is deposited. The intermediate layer 500 may be formed through evaporation, sputtering, spin coating, knife coating, casting, electroplating, screen printing, inkjet printing, self-assembly, etc. In this embodiment, the intermediate layer 500 is an elastomer.

Step S400, a through hole 510 is formed in the intermediate layer 500 to expose the first conductor 110 partially, and the third conductor 130 electrically connected with the first conductor 110 is formed in the through hole 510. Preferably, the through hole 510 is perpendicular to the first conductor 110, so that the formed third conductor 130 is perpendicular to the first conductor 110. In the case of a plurality of first conductors 110 and a plurality of third conductors 130, in this step, a plurality of through holes 510 are formed at intervals in the intermediate layer 500. herein, the through holes 510 are formed through photoetching etching; or in other embodiments, the through holes 510 are formed through screen printing, inkjet printing, self-assembly, etc.

Step S500, a second conductor 120 is formed on a surface of the intermediate layer 500 opposite the first base 400, wherein the second conductor 120 is connected with the third conductor 130, and the plane where the second conductor 120 and the third conductor 130 are positioned has a preset angle α between 0° and 180° in relation to the first conductor 110. The first conductor 110, the second conductor 120, and the third conductor 130 are connected altogether to form the elastic conductor 100, as described in the above embodiment. The second conductor 120 may be formed through deposition/plating, photolithography etching, screen printing, inkjet printing, self-assembly, etc. Herein, the second conductor 120 and the third conductor 130 may be made of the same or different materials, in other embodiments, the third conductor 130 and the second conductor 120 may be formed in one step when the materials are the same.

Step S600, a sub-elastomer is formed on a surface of the second conductor 120 opposite the first base 400 and covers the second conductor 120.

The elastic connecting component 10 manufactured by the method of this application has better tensile elongation performance.

Referring to FIG. 10, in a further embodiment, when the intermediate layer 500 is the first sub-elastomer 201, step S600 is step S600-I.

Step S600-I, a second sub-elastomer 202 is formed on a surface of the intermediate layer 500 opposite the first base 400 and covers the second conductor 120.

In a further embodiment, after step S600-I, the method for manufacturing the elastic connecting component further includes the following step.

Step S700-I, the first base 400 is removed, a fourth sub-elastomer 204 is formed on a surface of the intermediate layer 500 opposite the second sub-elastomer 202 and covers the first conductor 110. In this embodiment, the first base 400 includes the first sub-base 410, and thus the first sub-base 410 is removed in this step. The first sub-elastomer 201 and the second sub-elastomer 202 constitute the elastomer 200 in FIG. 1; the fourth sub-elastomer 204 is the elastic base 300 in FIG. 1; the first sub-elastomer 201, the second sub-elastomer 202 and the fourth sub-elastomer 204 encase the elastic conductor 100; the first sub-elastomer 201, the second sub-elastomer 202 and the fourth sub-elastomer 204 may be made of the same or different materials.

Referring to FIGS. 11 and 12, this application also provides another method for manufacturing the elastic connecting component 10 according to an embodiment, unlike the method described above, the intermediate layer 500 formed in the step S300 is not an elastomer, and the intermediate layer 500 may be made of materials such as oxides, nitrides, metal, inorganic salts, or organic materials. Step S600 is step S600-II.

Step S600-II, the intermediate layer 500 is removed, a third sub-elastomer 203 is formed on a side of the first base 400 facing the first conductor 100 and covers the first conductor 110, the second conductor 120, and the third conductor 130. The third sub-elastomer 203 is the elastomer 200 in FIG. 1.

In a further embodiment, after step S600-II, the method for manufacturing the elastic connecting component further includes the following step.

Step S700-II, the first base 400 is removed, a fifth sub-elastomer 205 is formed on a surface of the third sub-elastomer 203 close to the first conductor 110 and covers the first conductor 110. In this embodiment, the first base 400 includes the first sub-base 410, and thus the first sub-base 410 is removed in this step. Herein, the fifth sub-elastomer 205 is the elastic base 300 in FIG. 1.

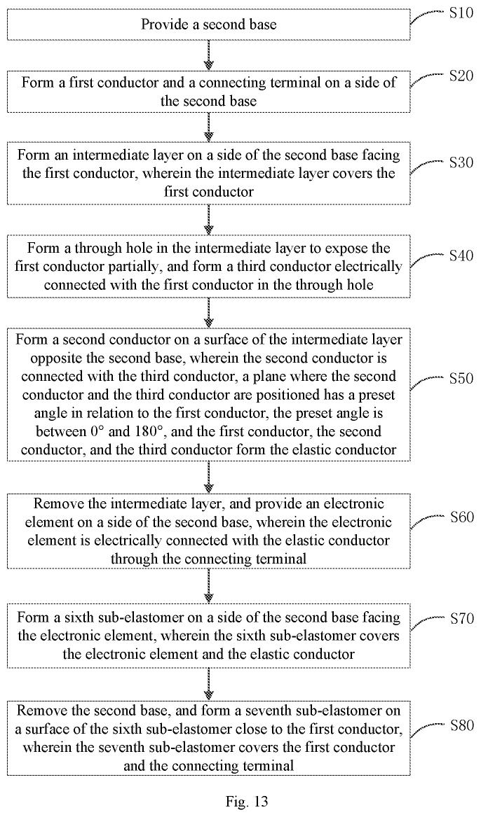

Referring to FIGS. 13 and 6, an embodiment of this application also provides a method for manufacturing an elastic electronic device 20, including step S10, step S20, step S30, step S40, step S50, step S60, and step S70. The details are as follows.

Step S10, a second base is provided. The second base is not shown in FIG. 6.

Step S20, a first conductor 110 and a connecting terminal 140 are formed on a side of the second base. The process for forming the elastic conductor 100 can be seen in FIG. 9.

Step S30, an intermediate layer 500 is formed on a side of the second base facing the first conductor 110 and covers the first conductor 110.

Step S40, a through hole 510 is formed in the intermediate layer 500 to expose the first conductor 110 partially, and the third conductor 130 electrically connected with the first conductor 110 is formed in the through hole 510. Herein, the through hole 510 at an end portion of the intermediate layer 500 is connected with the connecting terminal 140, so that the third conductor 130 formed at the end portion is connected with the connecting terminal 140. Herein, the connecting terminal 140 may be sheet-shaped, dot-shaped, or strip-shaped.

Step S50, a second conductor 120 is formed on a surface of the intermediate layer 500 opposite the second base, wherein the second conductor 120 is connected with the third conductor 130, and the plane where the second conductor 120 and the third conductor 130 are positioned has a preset angle α between 0° and 180° in relation to the first conductor 110; the first conductor 110, the second conductor 120, and the third conductor 130 constitute the elastic conductor 100.

Step S60, the intermediate layer 500 is removed, an electronic element 30 is provided on a side of the second base and electrically connected with the elastic conductor 100 through the connecting terminal 140.

Step S70, a sixth sub-elastomer 206 is formed on a side of the second base facing the electronic element 30 and covers the electronic element 30 and the elastic conductor 100.

In a further embodiment, after step S70, the method for manufacturing the elastic electronic device further includes the following step.

Step S80, the second base is removed, a seventh sub-elastomer 207 is formed on a surface of the sixth sub-elastomer 206 close to the first conductor 110 and covers the first conductor 110 and the connecting terminal 140. The sixth sub-elastomer 206 and the seventh sub-elastomer 207 together encase the electronic element 30 and the elastic conductor 100. The sixth sub-elastomer 206 and the seventh sub-elastomer 207 constitute the elastomer 200 in FIG. 6.

Referring to FIG. 7, in other embodiments, the connecting terminal 140 is not formed in step S20, specifically, the first conductor 110 is formed on a side of the second base. In step S60, after the electronic element 30 is arranged, the connecting terminal 140 is formed on a surface of the electronic element 30 opposite the second base, and the connecting terminal 140 is connected with the third conductor 130 at the end portion of the elastic conductor 100.

The above-described embodiments are only a few of the application, which are described in greater detail, and are not to be construed as limiting the scope of the application. It should be noted that several variations and modifications may be made by those skilled in the art without departing from the spirit of the application and shall fall within the scope of the application. Therefore, the scope of this application shall be determined by the appended claims.

1. An elastic connecting component, comprising an elastomer and an elastic conductor in the elastomer, wherein the elastic conductor comprises a first conductor, a second conductor, and a third conductor electrically connected between the first conductor and the second conductor, a plane where the second conductor and the third conductor are positioned has a preset angle in relation to the first conductor, and the preset angle is between 0° and 180°.

2. The elastic connecting component according to claim 1, wherein an included angle between the third conductor and a horizontal plane decreases when the elastic connecting component is pulled in tension in a case that an extension direction of the elastic connecting component is parallel to the horizontal plane.

3. The elastic connecting component according to claim 1, wherein adjacent ones of the first conductor, the second conductor and the third conductor form a conductive unit, and the elastic conductor comprises at least one conductive unit.

4. The elastic connecting component according to claim 1, wherein the third conductor is connected at adjacent ends of the first conductor and the second conductor.

5. The elastic connecting component according to claim 1, wherein the first conductor is parallel to the second conductor,
or the third conductor is perpendicularly connected with the first conductor and the second conductor, respectively, when the elastic connecting component is not pulled in tension.

6. The elastic connecting component according to claim 1, wherein the first conductor and the second conductor are sheet-like, and the third conductor is cylindrical.

7. The elastic connecting component according to claim 1, wherein the elastomer comprises a first surface, and the first conductor is arranged closer to the first surface of the elastomer than the second conductor; the elastic connecting component further comprises a flexible layer or an elastic base, the flexible layer is arranged on a surface of the first conductor close to the first surface, the elastic base is attached to the first surface of the elastomer.

8. An elastic electronic device, comprising an elastic connecting component, wherein the elastic connecting component comprises an elastomer and an elastic conductor in the elastomer, and the elastic conductor comprises a first conductor, a second conductor, and a third conductor electrically connected between the first conductor and the second conductor, a plane where the second conductor and the third conductor are positioned has a preset angle in relation to the first conductor, and the preset angle is between 0° and 180°.

9. The elastic electronic device according to claim 8, further comprising an electronic element arranged in the elastomer and electrically connected with the elastic conductor.

10. The elastic electronic device according to claim 8, wherein an included angle between the third conductor and a horizontal plane decreases when the elastic connecting component is pulled in tension in a case that an extension direction of the elastic connecting component is parallel to the horizontal plane.

11. The elastic electronic device according to claim 8, wherein adjacent ones of the first conductor, the second conductor and the third conductor form a conductive unit, and the elastic conductor comprises at least one conductive unit.

12. The elastic electronic device according to claim 8, wherein the third conductor is connected at adjacent ends of the first conductor and the second conductor.

13. The elastic electronic device according to claim 8, wherein the first conductor is parallel to the second conductor, or the third conductor is perpendicularly connected with the first conductor and the second conductor, respectively, when the elastic connecting component is not pulled in tension.

14. The elastic electronic device according to claim 8, wherein the first conductor and the second conductor are sheet-like, and the third conductor is cylindrical.

15-20. (canceled)

21. A method for manufacturing an elastic connecting component, the method comprising:
providing a first base;
forming a first conductor on a first side of the first base;
forming an intermediate layer on the first side of the first base facing the first conductor, wherein the intermediate layer covers the first conductor;
forming a through hole in the intermediate layer to partially expose the first conductor;
forming a third conductor electrically connected with the first conductor in the through hole;
forming a second conductor on a surface of the intermediate layer opposite the first base; and
forming a sub-elastomer on a surface of the second conductor opposite the first base,
wherein the sub-elastomer covers the second conductor,
wherein the second conductor is electrically connected with the third conductor, and
wherein the second conductor and the third conductor share a plane, and the plane forms an angle between 0° and 180° relative to the first conductor.

22. The method according to claim 21, wherein forming a sub-elastomer on a surface of the second conductor opposite the first base further comprises:
forming a second sub-elastomer on a surface of the intermediate layer opposite the first base, wherein the second sub-elastomer covers the second conductor, and the intermediate layer is a first sub-elastomer.

23. The method according to claim 21, wherein forming a sub-elastomer on a surface of the second conductor opposite the first base further comprises:
removing the intermediate layer; and
forming a third sub-elastomer on a side of the first base facing the first conductor, wherein the third sub-elastomer covers the first conductor, the second conductor, and the third conductor,
wherein the intermediate layer is not an elastomer.

24. The method according to claim 21, wherein forming a first conductor on a side of the first base further comprises:
forming the first conductor on a surface of a flexible base of the first base opposite a first sub-base of the first base; and
after forming the first conductor, reducing the flexible base to a flexible layer, wherein the flexible layer at least coincides with the first conductor,
wherein, after reducing the flexible base to a flexible layer, forming the intermediate layer further comprises:
forming the intermediate layer on a side of the first sub-base facing the first conductor, wherein the intermediate layer covers the first conductor and the flexible layer.

25. The method according to claim 22, further comprising, after forming the second sub-elastomer:
removing the first base; and
forming a fourth sub-elastomer on a surface of the intermediate layer opposite the second sub-elastomer, wherein the fourth sub-elastomer covers the first conductor.

26. The method according to claim 23, further comprising, after removing the intermediate layer and after forming the third sub-elastomer:
removing the first base; and
forming a fifth sub-elastomer on a surface of the third sub-elastomer close to the first conductor, wherein the fifth sub-elastomer covers the first conductor.
